(19) United States
(12) Patent Application Publication
(10) Pub. No.: US 2024/0266389 A1
(43) Pub. Date: Aug. 8, 2024

(54) SEMICONDUCTOR DEVICE

(71) Applicant: FUJI ELECTRIC CO., LTD., Kanagawa (JP)

(72) Inventors: Yoshiharu KATO, Matsumoto-city (JP); Kaname MITSUZUKA, Matsumoto-city (JP); Tohru SHIRAKAWA, Matsumoto-city (JP); Yuuki ODA, Matsumoto-city (JP)

(21) Appl. No.: 18/611,716

(22) Filed: Mar. 21, 2024

Related U.S. Application Data
(63) Continuation of application No. PCT/JP2023/016589, filed on Apr. 27, 2023.

(30) Foreign Application Priority Data
Apr. 27, 2022 (JP) 2022-073381

(51) Int. Cl. H01L 29/06; H01L 29/739; H01L 29/78

(52) U.S. Cl. CPC H01L 29/0619; H01L 29/063; H01L 29/7397; H01L 29/7805

(57) ABSTRACT

Provided is a semiconductor device including: a semiconductor substrate having an upper surface and a lower surface and having a drift region of a first conductivity type; and a buffer region of the first conductivity type provided between the drift region and the lower surface of the semiconductor substrate and having a higher doping concentration than the drift region, wherein the buffer region has: a first recombination center density peak; and a second recombination center density peak arranged on a side of the upper surface of the semiconductor substrate relative to the first recombination center density peak, and an integrated value of the second recombination center density peak in a depth direction is greater than an integrated value of the first recombination center density peak in the depth direction.

The contents of the following patent application(s) are incorporated herein by reference:
NO. 2022-073381 filed in JP on Apr. 27, 2022
NO. PCT/JP2023/016589 filed in WO on Apr. 27, 2023

### BACKGROUND

### 1. Technical Field

The present invention relates to a semiconductor device.

### 2. Related Art

In the prior art, a technique is known in which lattice defects are formed by implanting particles such as helium into a semiconductor device (see, for example, Patent Documents 1 and 2).

### PRIOR ART DOCUMENT

### Patent Document

Patent Document 1: WO2019/181852
Patent Document 2: WO2017/146148

### BRIEF DESCRIPTION OF THE DRAWINGS

FIG. 1 is a top view showing an example of a semiconductor device 100.

FIG. 2 is an enlarged view of a region D in FIG. 1.

FIG. 3 illustrates an example of a cross section e-e in FIG. 2.

FIG. 4A illustrates examples of a doping concentration distribution, a hydrogen chemical concentration distribution, a helium chemical concentration distribution, and a recombination center density distribution along a line F-F in FIG. 3.

FIG. 4B illustrates relationships between an implantation depth of ions (Rp) and acceleration energy required for implantation.

FIG. 4C illustrates relationships between the implantation depth of ions (Rp) and a straggling (ΔRp, a standard deviation) in an implantation direction.

FIG. 5 illustrates a first recombination center density peak 220-1 and a second recombination center density peak 220-2.

FIG. 6 illustrates examples of a doping concentration distribution, a hydrogen chemical concentration distribution, a helium chemical concentration distribution, a recombination center density distribution, and an integrated concentration distribution of a doping concentration in a buffer region 20.

FIG. 7 illustrates relationships between helium dose amounts at a first recombination center density peak 220-1 and a second recombination center density peak 220-2, and a reverse recovery loss Err.

FIG. 8 illustrates relationships between helium dose amounts at a first recombination center density peak 220-1 and a second recombination center density peak 220-2, and a leakage current Ices.

FIG. 9 shows examples of a carrier concentration distribution and a helium chemical concentration distribution in a buffer region 20 according to a comparative example.

FIG. 10 illustrates other examples of a doping concentration distribution, a hydrogen chemical concentration distribution, a helium chemical concentration distribution, a recombination center density distribution, and an integrated concentration distribution of a doping concentration in a buffer region 20.

FIG. 11 describes inter-peak regions in a buffer region 20.

FIG. 12 illustrates some processes in a method for manufacturing a semiconductor device 100.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other members is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When a Z axis direction is described without describing the signs, it means that the direction is parallel to a +Z axis and a −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

Further, a region from the center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type or a semiconductor presenting a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to impurities themselves. For example, a VOH defect in which a vacancy (V), oxygen (O), and hydrogen (H) present in the semiconductor are attached together functions as a donor which supplies electrons. In addition, a Sii-H defect caused by interstitial silicon and hydrogen, and a CiOi-H defect caused by interstitial carbon and interstitial oxygen and hydrogen may also function as donors which supply electrons. In the present specification, the VOH defect, the Sii-H defect, or the CiOi-H defect may be referred to as a hydrogen donor.

In the semiconductor substrate of the present specification, bulk donors of the N type are distributed throughout. The bulk donor is a dopant donor substantially uniformly contained in an ingot at the time of manufacturing the ingot from which the semiconductor substrate is made. The bulk donor in this example is an element other than hydrogen. The bulk donor dopant is, for example, phosphorous, antimony, arsenic, selenium, or sulfur, but the invention is not limited thereto. The bulk donor in this example is phosphorous. The bulk donor is also contained in a region of the P type. The semiconductor substrate may be a wafer cut out from a semiconductor ingot, or may be a chip obtained by singulating the wafer. The semiconductor ingot may be manufactured by either a Czochralski method (CZ method), a magnetic field applied Czochralski method (MCZ method), or a float zone method (FZ method). The ingot in this example is manufactured by the MCZ method. An oxygen concentration contained in the substrate manufactured by the MCZ method is 1×10¹⁷ to 7×10¹⁷/cm³. The oxygen concentration contained in the substrate manufactured by the FZ method is 1×10¹⁵ to 5×10¹⁶/cm³. When the oxygen concentration is high, hydrogen donors tend to be easily generated. The bulk donor concentration may use a chemical concentration of bulk donors distributed throughout the semiconductor substrate, or may be a value between 90% and 100% of the chemical concentration. Further, as the semiconductor substrate, a non-doped substrate not containing a dopant such as phosphorous may be used. In that case, the bulk donor concentration (DO) of the non-doped substrate is, for example, from 1×10¹⁰/cm³ or more and to 5×10¹²/cm³ or less. The bulk donor concentration (D0) of the non-doped substrate is preferably 1×10¹¹/cm³ or more. The bulk donor concentration (D0) of the non-doped substrate is preferably 5×10¹²/cm³ or less. It should be noted that each concentration in the present invention may be a value at room temperature. As an example, a value at 300K (Kelvin) (about 26.9 degrees C.) may be used as the value at room temperature.

In the present specification, a description of a P+ type or an N+ type means a higher doping concentration than that of the P type or the N type, and a description of a P− type or an N− type means a lower doping concentration than that of the P type or the N type. Further, in the present specification, a description of a P++ type or an N++ type means a higher doping concentration than that of the P+ type or the N+ type. In the present specification, a unit system is the SI base unit system unless otherwise specified. Although a unit of length is represented using cm, it may be converted to meters (m) before calculations.

A chemical concentration in the present specification refers to an atomic density of an impurity measured regardless of an electrical activation state. The chemical concentration can be measured by, for example, a secondary ion mass spectrometry (SIMS). The net doping concentration described above can be measured by capacitance-voltage profiling (CV method). In addition, a carrier concentration measured by spreading resistance profiling (SRP method) may be set as the net doping concentration. A carrier means an electron charge carrier or a hole charge carrier. The carrier concentration measured by the CV method or the SRP method may be a value in a thermal equilibrium state. In addition, in a region of the N type, the donor concentration is sufficiently higher than the acceptor concentration, and thus the carrier concentration in the region may be defined as the donor concentration. Similarly, in a region of the P type, the carrier concentration in the region may be defined as the acceptor concentration. In the present specification, the doping concentration in the N type region may be referred to as the donor concentration, and the doping concentration in a P type region may be referred to as the acceptor concentration.

In addition, when a concentration distribution of the donor, acceptor, or net doping has a peak in a region, a value of the peak may be defined as the concentration of the donor, acceptor, or net doping in the region. In a case where the concentration of the donor, acceptor or net doping is substantially uniform in a region, or the like, an average donor, acceptor or net doping concentration in the region may be defined as a donor, acceptor or net doping concentration. In the present specification, atoms/cm³ or/cm³ is used to indicate a concentration per unit volume. This unit is used for a concentration of a donor or an acceptor in a semiconductor substrate, or a chemical concentration. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in the carrier mobility occurs when carriers are scattered due to disorder (disorder) of a crystal structure due to a lattice defect or the like. The carrier concentration decreases for the following reason. In the SRP method, a spreading resistance is measured, and the carrier concentration is converted from a measurement value of the spreading resistance. At this time, mobility of the crystalline state is used as the carrier mobility. On the other hand, despite the fact that the carrier mobility has decreased at a position where the lattice defect is introduced, the carrier concentration is calculated by using the carrier mobility of the crystalline state. Therefore, a value lower than an actual carrier concentration, that is, a concentration of the donor or the acceptor, is obtained.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

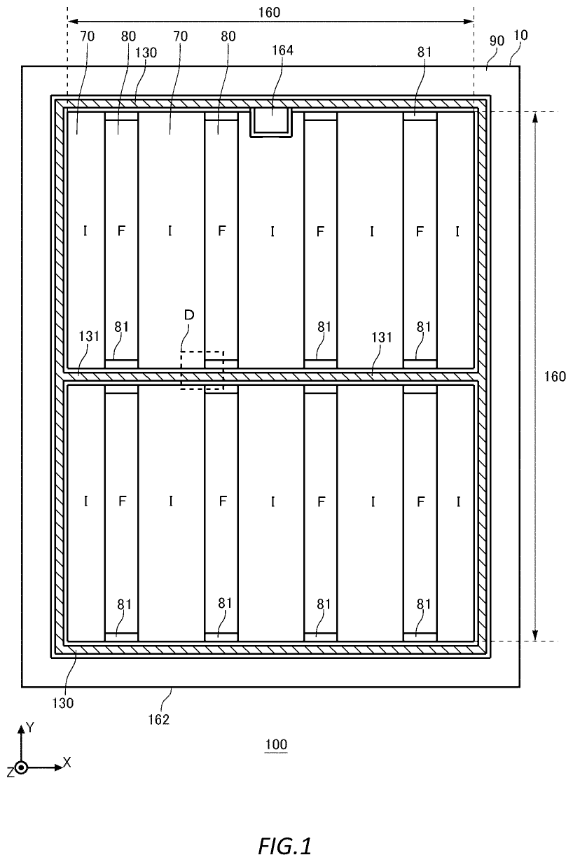

FIG. 1 is a top view showing an example of a semiconductor device 100. FIG. 1 shows a position at which each member is projected on an upper surface of a semiconductor substrate 10. FIG. 1 shows merely some members of the semiconductor device 100, and omits illustrations of some members.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has an end side 162 in a top view. When simply referred to as the top view in the present specification, it means that the semiconductor substrate 10 is viewed from an upper surface side. The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in the depth direction between the upper surface and a lower surface of the semiconductor substrate 10 when the semiconductor device 100 operates. An emitter electrode is provided above the active portion 160, but is omitted in FIG. 1.

The active portion 160 is provided with at least one of a transistor portion 70 including a transistor element such as an IGBT, and a diode portion 80 including a diode element such as a freewheeling diode (FWD). In the example of FIG. 1, the transistor portion 70 and the diode portion 80 are alternately arranged along a predetermined array direction (the X axis direction in this example) on the upper surface of the semiconductor substrate 10. The active portion 160 in another example may be provided with only one of the transistor portion 70 and the diode portion 80.

In FIG. 1, a region where each of the transistor portions 70 is arranged is indicated by a symbol “I”, and a region where each of the diode portions 80 is arranged is indicated by a symbol “F”. In the present specification, a direction perpendicular to the array direction in a top view may be referred to as an extending direction (the Y axis direction in FIG. 1). Each of the transistor portions 70 and the diode portions 80 may have a longitudinal length in the extending direction. That is, the length of each of the transistor portions 70 in the Y axis direction is greater than the width in the X axis direction. Similarly, the length of each of the diode portions 80 in the Y axis direction is greater than the width in the X axis direction. The extending direction of the transistor portion 70 and the diode portion 80, and the longitudinal direction of each trench portion described below may be the same.

Each of the diode portions 80 includes a cathode region of N+ type in a region in contact with the lower surface of the semiconductor substrate 10. In the present specification, a region where the cathode region is provided is referred to as the diode portion 80. That is, the diode portion 80 is a region that overlaps with the cathode region in a top view. On the lower surface of the semiconductor substrate 10, a collector region of a P+ type may be provided in a region other than the cathode region. In the present specification, the diode portion 80 may also include an extension region 81 where the diode portion 80 extends to a gate runner described below in the Y axis direction. The collector region is provided on a lower surface of the extension region 81.

The transistor portion 70 has the collector region of the P+ type in a region in contact with the lower surface of the semiconductor substrate 10. Further, in the transistor portion 70, an emitter region of an N type, a base region of a P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 in this example has a gate pad 164. The semiconductor device 100 may have a pad such as an anode pad, a cathode pad, and a current detection pad. Each pad is arranged in the vicinity of the end side 162. The vicinity of the end side 162 refers to a region between the end side 162 and the emitter electrode in a top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner in this example has an outer circumferential gate runner 130 and an active-side gate runner 131. The outer circumferential gate runner 130 is arranged between the active portion 160 and the end side 162 of the semiconductor substrate 10 in a top view. The outer circumferential gate runner 130 in this example encloses the active portion 160 in a top view. A region enclosed by the outer circumferential gate runner 130 in a top view may be the active portion 160. Further, the outer circumferential gate runner 130 is connected to the gate pad 164. The outer circumferential gate runner 130 is arranged above the semiconductor substrate 10. The outer circumferential gate runner 130 may be a metal wiring line containing aluminum or the like.

The active-side gate runner 131 is provided in the active portion 160. Providing the active-side gate runner 131 in the active portion 160 can reduce a variation in wiring length from the gate pad 164 for each region of the semiconductor substrate 10.

The active-side gate runner 131 is connected to the gate trench portion of the active portion 160. The active-side gate runner 131 is arranged above the semiconductor substrate 10. The active-side gate runner 131 may be a wiring line formed of a semiconductor such as polysilicon doped with an impurity.

The active-side gate runner 131 may be connected to the outer circumferential gate runner 130. The active-side gate runner 131 in this example is provided extending in the X axis direction so as to cross the active portion 160 from one outer circumferential gate runner 130 to another other outer circumferential gate runner 130 substantially at the center of the Y axis direction, the outer circumferential gate runner 130 sandwiching the active portion 160. When the active portion 160 is divided by the active-side gate runner 131, the transistor portion 70 and the diode portion 80 may be alternately arranged in the X axis direction in each divided region.

Further, the semiconductor device 100 may include a temperature sensing portion (not shown) that is a PN junction diode formed of polysilicon or the like, and a current detection portion (not shown) that simulates an operation of the transistor portion provided in the active portion 160.

The semiconductor device 100 in this example includes an edge termination structure portion 90 between the active portion 160 and the end side 162 in a top view. The edge termination structure portion 90 in this example is arranged between the outer circumferential gate runner 130 and the end side 162. The edge termination structure portion 90 reduces an electric field strength on the upper surface side of the semiconductor substrate 10. The edge termination structure portion 90 may include at least one of a guard ring, a field plate, and a RESURF which are annularly provided to enclose the active portion 160.

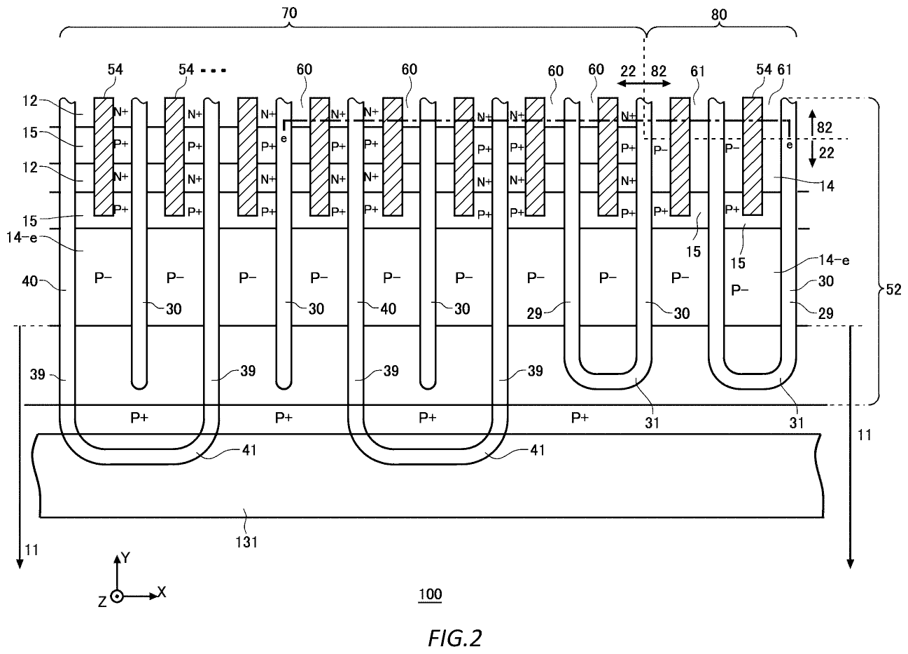

FIG. 2 is an enlarged view of a region D in FIG. 1. The region D is a region including the transistor portion 70, the diode portion 80, and the active-side gate runner 131. The semiconductor device 100 in this example includes a gate trench portion 40, a dummy trench portion 30, a well region 11, an emitter region 12, a base region 14, and a contact region 15 which are provided inside the upper surface side of the semiconductor substrate 10. The gate trench portion 40 and the dummy trench portion 30 each are an example of the trench portion. Further, the semiconductor device 100 in this example includes an emitter electrode 52 and the active-side gate runner 131 that are provided above the upper surface of the semiconductor substrate 10. The emitter electrode 52 and the active-side gate runner 131 are provided in isolation from each other.

An interlayer dielectric film is provided between the emitter electrode 52 and the active-side gate runner 131, and the upper surface of the semiconductor substrate 10, but the interlayer dielectric film is omitted in FIG. 2. In the interlayer dielectric film in this example, a contact hole 54 is provided passing through the interlayer dielectric film. In FIG. 2, each contact hole 54 is hatched with the diagonal lines.

The emitter electrode 52 is provided on the upper side of the gate trench portion 40, the dummy trench portion 30, the well region 11, the emitter region 12, the base region 14, and the contact region 15. The emitter electrode 52 is in contact with the emitter region 12, the contact region 15, and the base region 14 on the upper surface of the semiconductor substrate 10, through the contact hole 54. Further, the emitter electrode 52 is connected to a dummy conductive portion in the dummy trench portion 30 through the contact hole provided in the interlayer dielectric film. The emitter electrode 52 may be connected to the dummy conductive portion of the dummy trench portion 30 at an edge of the dummy trench portion 30 in the Y axis direction.

The active-side gate runner 131 is connected to the gate trench portion 40 through the contact hole provided in the interlayer dielectric film. The active-side gate runner 131 may be connected to a gate conductive portion of the gate trench portion 40 at an edge portion 41 of the gate trench portion 40 in the Y axis direction. The active-side gate runner 131 is not connected to the dummy conductive portion in the dummy trench portion 30.

The emitter electrode 52 is formed of a material including a metal. FIG. 2 shows a range where the emitter electrode 52 is provided. For example, at least part of a region of the emitter electrode 52 is formed of aluminum or an aluminum-silicon alloy, for example, a metal alloy such as AlSi, AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in the contact hole.

The well region 11 is provided overlapping the active-side gate runner 131. The well region 11 is provided so as to extend with a predetermined width even in a range not overlapping the active-side gate runner 131. The well region 11 in this example is provided away from an end of the contact hole 54 in the Y axis direction toward the active-side gate runner 131 side. The well region 11 is a region of a second conductivity type having a higher doping concentration than the base region 14. The base region 14 in this example is a P− type, and the well region 11 is a P+ type.

Each of the transistor portion 70 and the diode portion 80 includes a plurality of trench portions arrayed in the array direction. In the transistor portion 70 in this example, one or more gate trench portions 40 and one or more dummy trench portions 30 are alternately provided along the array direction. In the diode portion 80 in this example, the plurality of dummy trench portions 30 are provided along the array direction. In the diode portion 80 in this example, the gate trench portion 40 is not provided.

The gate trench portion 40 in this example may have two linear portions 39 extending along the extending direction perpendicular to the array direction (portions of a trench that are linear along the extending direction), and the edge portion 41 connecting the two linear portions 39. The extending direction in FIG. 2 is the Y axis direction.

At least a part of the edge portion 41 is preferably provided in a curved-line shape in a top view. By connecting between end portions of the two linear portions 39 in the Y axis direction by the edge portion 41, it is possible to reduce the electric field strength at the end portions of the linear portions 39.

In the transistor portion 70, the dummy trench portions 30 are provided between the respective linear portions 39 of the gate trench portions 40. Between the respective linear portions 39, one dummy trench portion 30 may be provided, or a plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 2 includes both of the linear dummy trench portion 30 having no edge portion 31, and the dummy trench portion 30 having the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. That is, a bottom portion in the depth direction of each trench portion is covered with the well region 11 at the end portion in the Y axis direction of each trench portion. With this configuration, the electric field strength on the bottom portion of each trench portion can be reduced.

A mesa portion is provided between the respective trench portions in the array direction. The mesa portion refers to a region sandwiched between the trench portions inside the semiconductor substrate 10. As an example, an upper end of the mesa portion is the upper surface of the semiconductor substrate 10. The depth position of the lower end of the mesa portion is the same as the depth position of the lower end of the trench portion. The mesa portion in this example is provided extending in the extending direction (the Y axis direction) along the trench, on the upper surface of the semiconductor substrate 10. In this example, a mesa portion 60 is provided in the transistor portion 70, and a mesa portion 61 is provided in the diode portion 80. In the case of simply mentioning “mesa portion” in the present specification, the portion refers to each of the mesa portion 60 and the mesa portion 61.

Each mesa portion is provided with the base region 14. In the mesa portion, a region arranged closest to the active-side gate runner 131, in the base region 14 exposed on the upper surface of the semiconductor substrate 10, is to be a base region 14-e. While FIG. 2 shows the base region 14-e arranged at one end portion of each mesa portion in the extending direction, the base region 14-e is also arranged at another end portion of each mesa portion. Each mesa portion may be provided with at least one of the emitter region 12 of a first conductivity type, and the contact region 15 of the second conductivity type in a region sandwiched between the base regions 14-e in a top view. The emitter region 12 in this example is an N+ type, and the contact region 15 is the P+ type. The emitter region 12 and the contact region 15 may be provided between the base region 14 and the upper surface of the semiconductor substrate 10 in the depth direction.

The mesa portion 60 of the transistor portion 70 has the emitter region 12 exposed on the upper surface of the semiconductor substrate 10. The emitter region 12 is provided in contact with the gate trench portion 40. The mesa portion 60 in contact with the gate trench portion 40 may be provided with the contact region 15 exposed on the upper surface of the semiconductor substrate 10.

Each of the contact region 15 and the emitter region 12 in the mesa portion 60 is provided from one trench portion to another trench portion in the X axis direction. As an example, the contact region 15 and the emitter region 12 in the mesa portion 60 are alternately arranged along the extending direction of the trench portion (the Y axis direction).

In another example, the contact region 15 and the emitter region 12 in the mesa portion 60 may be provided in a stripe shape along the extending direction of the trench portion (the Y axis direction). For example, the emitter region 12 is provided in a region in contact with the trench portion, and the contact region 15 is provided in a region sandwiched between the emitter regions 12.

The mesa portion 61 of the diode portion 80 is not provided with the emitter region 12. The base region 14 and the contact region 15 may be provided on an upper surface of the mesa portion 61. In the region sandwiched between the base regions 14-e on the upper surface of the mesa portion 61, the contact region 15 may be provided in contact with each base region 14-e. The base region 14 may be provided in a region sandwiched between the contact regions 15 on the upper surface of the mesa portion 61. The base region 14 may be arranged in the entire region sandwiched between the contact regions 15.

The contact hole 54 is provided above each mesa portion. The contact hole 54 is arranged in the region sandwiched between the base regions 14-e. The contact hole 54 in this example is provided above respective regions of the contact region 15, the base region 14, and the emitter region 12. The contact hole 54 is not provided in regions corresponding to the base region 14-e and the well region 11. The contact hole 54 may be arranged at the center of the mesa portion 60 in the array direction (the X axis direction).

In the diode portion 80, a cathode region 82 of the N+ type is provided in a region in direct contact with the lower surface of the semiconductor substrate 10. On the lower surface of the semiconductor substrate 10, a collector region 22 of the P+ type may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, the distance between a region of a P type (the well region 11) having a relatively high doping concentration and formed up to the deep position, and the cathode region 82 is ensured, so that the breakdown voltage can be improved. The end portion in the Y axis direction of the cathode region 82 in this example is arranged farther away from the well region 11 than the end portion in the Y axis direction of the contact hole 54. In another example, the end portion in the Y axis direction of the cathode region 82 may be arranged between the well region 11 and the contact hole 54.

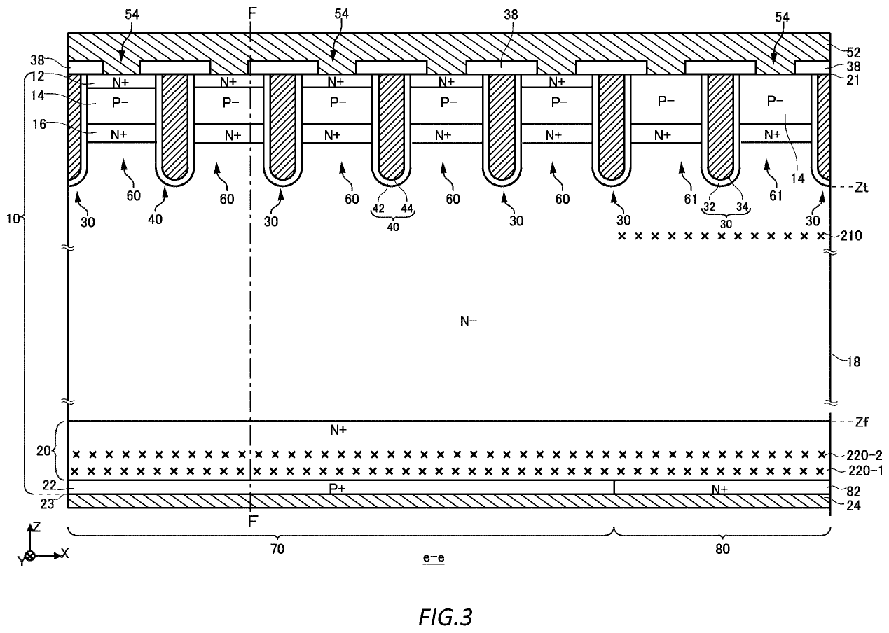

FIG. 3 illustrates an example of a cross section e-e in FIG. 2. The cross section e-e is an XZ plane passing through the emitter region 12 and the cathode region 82. The semiconductor device 100 in this example includes the semiconductor substrate 10, the interlayer dielectric film 38, the emitter electrode 52, and the collector electrode 24 in the cross section.

The interlayer dielectric film 38 is provided on the upper surface of the semiconductor substrate 10. The interlayer dielectric film 38 is a film including at least one of a dielectric film such as silicate glass to which an impurity such as boron or phosphorous is added, a thermal oxide film, and other dielectric films. The interlayer dielectric film 38 is provided with the contact hole 54 described with respect to FIG. 2.

The emitter electrode 52 is provided on the upper side of the interlayer dielectric film 38. The emitter electrode 52 is in contact with an upper surface 21 of the semiconductor substrate 10 through the contact hole 54 of the interlayer dielectric film 38. The collector electrode 24 is provided on a lower surface 23 of the semiconductor substrate 10. The emitter electrode 52 and the collector electrode 24 are formed of a metal material such as aluminum. In the present specification, the direction in which the emitter electrode 52 is connected to the collector electrode 24 (the Z axis direction) is referred to as a depth direction.

The semiconductor substrate 10 includes a drift region 18 of an N type or an N− type. The drift region 18 is provided in each of the transistor portion 70 and the diode portion 80.

In the mesa portion 60 of the transistor portion 70, the emitter region 12 of an N+ type and a base region 14 of a P− type are provided in order starting from an upper surface 21 side of the semiconductor substrate 10. The drift region 18 is provided below the base region 14. The mesa portion 60 may be provided with an accumulation region 16 of the N+ type. The accumulation region 16 is arranged between the base region 14 and the drift region 18.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the mesa portion 60.

The accumulation region 16 is provided below the base region 14. The accumulation region 16 is a region of the N+ type with a higher doping concentration than the drift region 18. That is, the accumulation region 16 has a higher donor concentration than the drift region 18. By providing the accumulation region 16 having the high concentration between the drift region 18 and the base region 14, it is possible to improve a carrier injection enhancement effect (IE effect) and reduce an on-voltage. The accumulation region 16 may be provided to cover a whole lower surface of the base region 14 in each mesa portion 60.

The mesa portion 61 of the diode portion 80 is provided with the base region 14 of the P− type in contact with the upper surface 21 of the semiconductor substrate 10. The drift region 18 is provided below the base region 14. In the mesa portion 61, the accumulation region 16 may be provided below the base region 14.

In each of the transistor portion 70 and the diode portion 80, a buffer region 20 of the N+ type may be provided below the drift region 18. The doping concentration of the buffer region 20 is higher than the doping concentration of the drift region 18. The buffer region 20 may have a concentration peak with a higher doping concentration than the drift region 18. The doping concentration of the concentration peak indicates a doping concentration at the local maximum of the concentration peak. Further, as the doping concentration of the drift region 18, an average value of doping concentrations in the region where the doping concentration distribution is substantially flat may be used.

The buffer region 20 may have two or more concentration peaks in the depth direction (the Z axis direction) of the semiconductor substrate 10. The concentration peak of the buffer region 20 may be provided at the same depth position as, for example, a chemical concentration peak of hydrogen (proton) or phosphorous. The buffer region 20 may function as a field stopper layer which prevents a depletion layer expanding from the lower end of the base region 14 from reaching the collector region 22 of a P+ type and the cathode region 82 of the N+ type. In the present specification, a depth position of an upper end of the buffer region 20 is set as Zf. The depth position Zf may be a position at which the doping concentration is higher than the doping concentration of the drift region 18.

In the transistor portion 70, the collector region 22 of the P+ type is provided below the buffer region 20. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

Below the buffer region 20 in the diode portion 80, the cathode region 82 of the N+ type is provided. A donor concentration of the cathode region 82 is higher than a donor concentration of the drift region 18. A donor of the cathode region 82 is, for example, hydrogen or phosphorous. It should be noted that an element serving as a donor and an acceptor in each region is not limited to the above described example. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each trench portion passes through the base region 14 from the upper surface 21 of the semiconductor substrate 10, and reaches the drift region 18. In a region where at least any one of the emitter region 12, the contact region 15, and the accumulation region 16 is provided, each trench portion also passes through the doping regions of these to reach the drift region 18. The configuration of the trench portion passing through the doping region is not limited to the one manufactured in the order of forming the doping region and then forming the trench portion. The configuration of the trench portion passing through the doping region includes a configuration of the doping region being formed between the trench portions after forming the trench portion.

As described above, the transistor portion 70 is provided with the gate trench portion 40 and the dummy trench portion 30. In the diode portion 80, the dummy trench portion 30 is provided, and the gate trench portion 40 is not provided. The boundary in the X axis direction between the diode portion 80 and the transistor portion 70 in this example is the boundary between the cathode region 82 and the collector region 22.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided inside from the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portions 30 may have the same structure as the gate trench portions 40 in the cross section. The dummy trench portion 30 includes a dummy trench provided in the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided inside the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 in this example are covered with the interlayer dielectric film 38 on the upper surface 21 of the semiconductor substrate 10. It should be noted that the bottom portions of the dummy trench portion 30 and the gate trench portion 40 may be formed in a curved-surface shape (a curved-line shape in the cross section) convexly downward. In the present specification, a depth position of a lower end of the gate trench portion 40 is set as Zt.

An upper surface-side lifetime killer may be provided on the upper surface 21 side of the semiconductor substrate 10. The upper surface-side lifetime killer is a recombination center of a lattice defect or the like locally formed in the depth direction. In this example, a recombination center density peak 210 in a recombination center density distribution in the depth direction is the upper surface-side lifetime killer. In each figure, a peak position of a density distribution of the lifetime killer in the depth direction is schematically indicated by an X mark. In the present specification, the peak position will be described as a position of the lifetime killer. X marks are discretely arranged in the X axis direction, but lifetime killers are uniformly provided in the X axis direction unless otherwise described.

The recombination center density peak 210 can be formed by implanting particles such as helium at a predetermined depth position from the upper surface 21 of the semiconductor substrate 10. A concentration peak of the particles such as helium may be arranged at the same depth position as that of the recombination center density peak 210. The recombination center density peak 210 may be arranged below each trench portion. In addition, the recombination center density peak 210 is preferably provided at a position where it does not overlap the gate trench portion 40 in a top view. As a result, the recombination center density peak 210 can be formed by implanting the particles such as helium without damaging the gate dielectric film 42. The recombination center density peak 210 in this example is provided throughout the diode portion 80 in a top view. The recombination center density peak 210 in FIG. 3 is not provided in the transistor portion 70, but in another example, the recombination center density peak 210 may be provided in part of a region of the transistor portion 70.

A lower surface-side lifetime killer is provided on a lower surface 23 side of the semiconductor substrate 10. The lower surface-side lifetime killer may be formed by implanting the particles such as helium from the lower surface 23 side of the semiconductor substrate 10. In this example, a recombination center density peak 220 is the lower surface-side lifetime killer. A plurality of recombination center density peaks 220 may be arranged at different positions in the depth direction. In the example shown in FIG. 3, a first recombination center density peak 220-1 and a second recombination center density peak 220-2 are arranged at different depth positions. Note that the recombination center density peaks 220 may be provided at three or more depth positions. A peak of a helium chemical concentration may be provided at the same depth position as that of each recombination center density peak 220.

Two or more recombination center density peaks 220 may be provided in the buffer region 20. This makes it easy to control a distribution of lifetime killers in the buffer region 20. Accordingly, a carrier lifetime can be precisely controlled.

The recombination center density peak 220 may be provided throughout the diode portion 80 in a top view. In addition, the recombination center density peak 220 may be provided throughout the transistor portion 70 in a top view. The recombination center density peak 220 may be provided throughout an active portion 160 in a top view, or may be provided throughout the semiconductor substrate 10 in a top view. The first recombination center density peak 220-1 and the second recombination center density peak 220-2 may be provided in the same range in a top view.

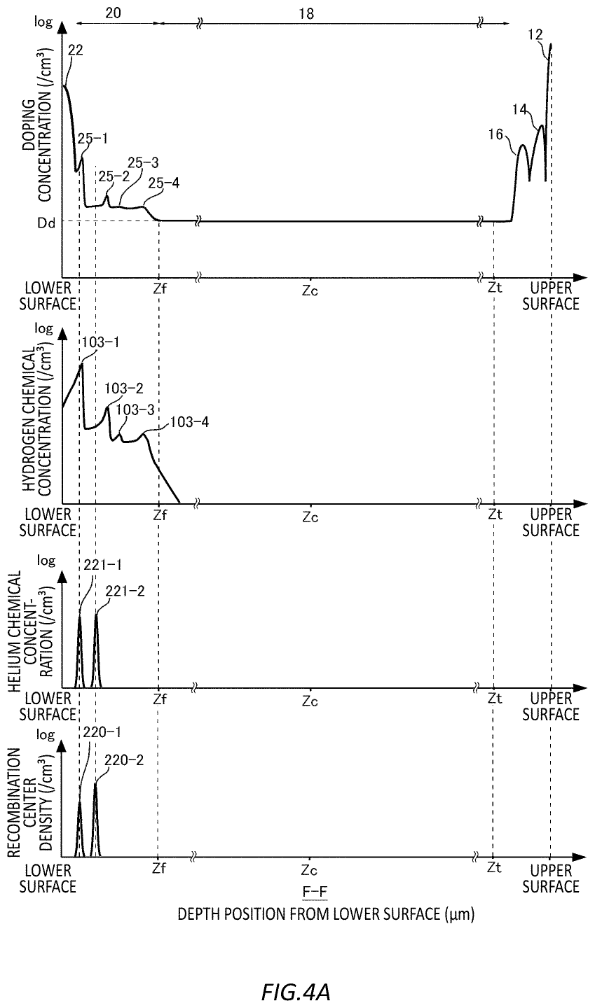

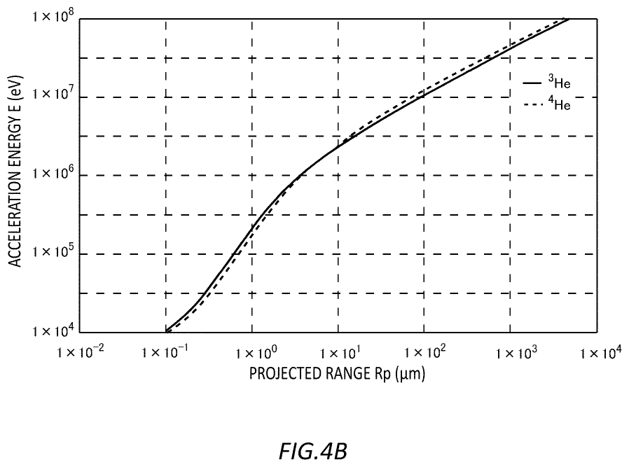

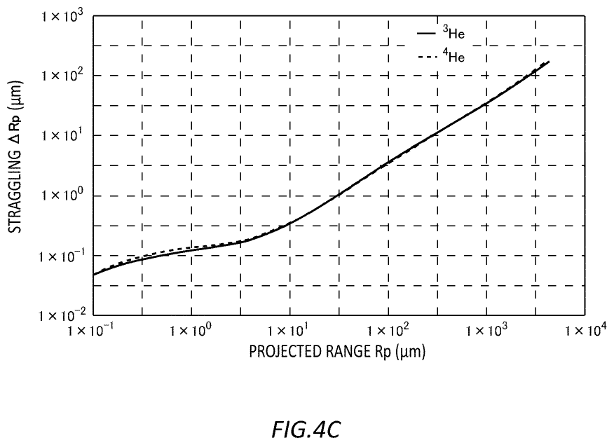

FIG. 4A illustrates examples of a doping concentration distribution, a hydrogen chemical concentration distribution, a helium chemical concentration distribution, and a recombination center density distribution along a line F-F in FIG. 3. In FIG. 4A, a center position of a semiconductor substrate 10 in a depth direction is defined as Zc. That is, a region on an upper surface 21 side of the semiconductor substrate 10 is a region between an upper surface 21 and the center position Zc, and a region on a lower surface 23 side is a region between a lower surface 23 and the center position Zc.

An emitter region 12 contains an N type dopant such as phosphorous. A base region 14 contains a P type dopant such as boron. An accumulation region 16 contains the N type dopant such as phosphorous or hydrogen. The doping concentration distribution may have respective concentration peaks in the emitter region 12, the base region 14, and the accumulation region 16.

A drift region 18 is a region having a substantially flat doping concentration. A doping concentration Dd of the drift region 18 may be the same as a bulk donor concentration of the semiconductor substrate 10, or may be higher than the bulk donor concentration.

A buffer region 20 in this example has a plurality of doping concentration peaks 25-1, 25-2, 25-3, and 25-4 in the doping concentration distribution. Each doping concentration peak 25 may be a peak of hydrogen donors formed by locally implanting hydrogen ions. In another example, each doping concentration peak 25 may be formed by implanting the N type dopant such as phosphorous. In another example, the N type dopant of the doping concentration peak 25-1 closest to the lower surface 23 may be defined as phosphorous, and N type dopants of the doping concentration peaks 25-2, 25-3, and 25-4, which are doping concentrations other than the doping concentration peak 25-1, may be defined as hydrogen. That is, the doping concentration peak 25-1 may be a concentration peak of phosphorous, and the doping concentration peaks 25 other than the doping concentration peak 25-1 may be concentration peaks of the hydrogen donors. In this case, there may not be a hydrogen chemical concentration peak 103-1 at a depth position of the doping concentration peak 25-1. A collector region 22 contains the P type dopant such as boron. In addition, the cathode region 82 shown in FIG. 3 contains the N type dopant such as phosphorous. In the buffer region 20, a concentration obtained by subtracting the doping concentration Dd of the drift region 18 from the doping concentration may be defined as a hydrogen donor concentration.

The hydrogen chemical concentration distribution in this example has a plurality of local hydrogen chemical concentration peaks 103 in the buffer region 20. The hydrogen donors in which hydrogen, lattice defects, and the like are attached together are formed by implanting hydrogen ions into the buffer region 20, and they function as donors. A hydrogen chemical concentration peak 103 in this example is provided at the same depth position as that of a doping concentration peak 25. Two peaks being provided at the same depth position means that a local maximum of one peak is arranged within a range of a full width at half maximum of another peak. When a concentration of the hydrogen chemical concentration peak 103 is not sufficiently high, the doping concentration peak 25 which is clear may not be observed at the same depth position as that of the hydrogen chemical concentration peak 103. The hydrogen chemical concentration in this example steeply decreases immediately after entering the drift region 18 from the buffer region 20. Therefore, the hydrogen donors are hardly formed in the drift region 18. In another example, hydrogen may diffuse into the drift region 18 to form the hydrogen donors. In this case, the doping concentration of the drift region 18 becomes higher than the bulk donor concentration.

The buffer region 20 has two or more helium chemical concentration peaks 221 arranged at different positions of the semiconductor substrate 10 in the depth direction. In this example, a first helium chemical concentration peak 221-1 and a second helium chemical concentration peak 221-2 are provided in the buffer region 20. The second helium chemical concentration peak 221-2 is arranged farther away from the lower surface 23 than the first helium chemical concentration peak 221-1.

As described above, a recombination center density peak 220 is formed in the vicinity of each helium chemical concentration peak 221. That is, the first helium chemical concentration peak 221-1 and the second helium chemical concentration peak 221-2 are provided at positions where they overlap the first recombination center density peak 220-1 and the second recombination center density peak 220-2. Overlapping peaks may mean that a local maximum of one peak is arranged within a full width at half maximum of another peak.

In this example, the first recombination center density peak 220-1 and the second recombination center density peak 220-2 are provided in the buffer region 20. The second recombination center density peak 220-2 is arranged farther away from the lower surface 23 than (that is, arranged on the upper surface 21 side relative to) the first recombination center density peak 220-1. The recombination center density peak 220 may be a recombination center which enhances carrier recombination. The recombination center may be a lattice defect. Lattice defects may be mainly composed of vacancies such as monatomic vacancies (V) or diatomic vacancies (VV), may be dislocations, may be interstitial atoms, or may be transition metals or the like. For example, atoms adjacent to the vacancies have dangling bonds. In a broad sense, the lattice defects may also include donors and acceptors, but in the present specification, the lattice defects mainly composed of vacancies may be referred to as vacancy-type lattice defects, vacancy-type defects, or simply lattice defects. In the present specification, the lattice defect may be referred to as a lifetime killer or simply a recombination center as the recombination center contributing to the carrier recombination. The lifetime killer may be formed by implanting helium ions into the semiconductor substrate 10. Since the lifetime killer formed by implanting helium may be terminated with hydrogen present in the buffer region 20, a depth position of a density peak of the lifetime killer may not match a depth position of the helium chemical concentration peak 221.

Implanting helium at two or more depth positions in the buffer region 20 makes it easy to control a density distribution of the recombination center density peak 220 in the buffer region 20. ³He or ⁴He may be implanted at each depth position. ³He is a helium isotope containing two protons and one neutron. ⁴He is a helium isotope containing two protons and two neutrons.

A half value width of a concentration peak of a helium chemical concentration in the depth direction can be decreased by implanting ³He or ⁴He with the lowest acceleration energy which uniquely determines an implantation depth, with no intervention of a buffer material (aluminum or the like).

FIG. 4B illustrates relationships between an implantation depth of ions (Rp) and acceleration energy required for implantation. In this example, the helium ions are directly implanted into the semiconductor substrate 10 made of silicon, with no intervention of the buffer material. In FIG. 4B, a horizontal axis represents a projected range Rp (μm), and a vertical axis represents acceleration energy E (eV) required for implantation. In FIG. 4B, an example for ³He is indicated by a solid line, and an example for ⁴He is indicated by a broken line.

log₁₀ (Rp) is defined as x, and log₁₀ (E) is defined as y. In ³He, a relationship between the projected range Rp and the acceleration energy E may be given by Equation 1:

y=4.52505E-03x⁶−4.71471E-02x⁵+1.67185E-01x⁴−1.72038E-01x³−2.92723E-01x²+1.39782E+00x+5.33858E+00 Equation 1

It should be noted that E−A is 10^{-A}, and E+A is 10^{A}.

The acceleration energy calculated by substituting an actual projected range Rp′ at the time of manufacturing the semiconductor device 100 into Equation 1 is defined as E. When an actual acceleration energy E′ at the time of manufacture is within ±20% of the acceleration energy E calculated from Equation 1, it may be considered that ³He is used.

In ⁴He, a relationship between the projected range Rp and the acceleration energy E may be given by Equation 2:

y=2.90157E-03x⁶−3.66593E-02x⁵+1.59363E-01x⁴−2.31938E-01x³−2.00999E-01x²+1.45891E+00x+5.27160E+00 Equation 2

When the actual acceleration energy E′ at the time of manufacture is within ±20% of the acceleration energy E calculated from Equation 2 by using the actual projected range Rp′, it may be considered that ⁴He is used.

As shown in FIG. 4B, when the projected range Rp is equal to or greater than a boundary value with a value of a region where the projected range Rp is 8 μm to 10 μm being as the boundary value, the acceleration energy of ⁴He is approximately 10% higher than the acceleration energy of ³He. When the projected range Rp is equal to or smaller than the boundary value, the acceleration energy of ³He is approximately 10% higher than the acceleration energy of ⁴He. This is presumed to be due to changes in a balance between an electronic stopping power and a nuclear stopping power depending on the number of neutrons of the isotope. As an example, when the projected range Rp is 10 μm or less, ⁴He may be used. This allows the helium ions to be implanted with the acceleration energy which is approximately 10% lower. When the projected range Rp is greater than 10 μm, ³He may be used.

FIG. 4C illustrates relationships between the implantation depth of ions (Rp) and a straggling (ΔRp, a standard deviation) in an implantation direction. The implantation direction in this example is the depth direction of the semiconductor substrate 10. Also in this example, the helium ions are directly implanted into the semiconductor substrate 10 made of silicon, with no intervention of the buffer material. In FIG. 4C, a horizontal axis represents the projected range Rp (μm), and a vertical axis represents the straggling ΔRp (μm). In FIG. 4C, an example for ³He is indicated by a solid line, and an example for ⁴He is indicated by a broken line.

The straggling ΔRp may be calculated assuming that a helium concentration distribution is a Gaussian distribution. For example, the straggling ΔRp may be a distance (a distribution width) between two points having a concentration of 0.60653 times a concentration peak value, or may be a distance between two points having a concentration of 0.6 times the concentration peak value. When a local minimum value or the like between adjacent concentration peaks is greater than 0.6 times the concentration peak value, a distance between inflection points such as a local minimum value of a concentration distribution may be used as the straggling ΔRp.

log₁₀(Rp) is defined as x, and log₁₀(ΔRp) is defined as y. In ³He, a relationship between the projected range Rp and the straggling ΔRp may be given by Equation 3:

y=5.00395E-04x⁶+9.91651E-03x⁵−9.76015E-02x⁴+2.12587E-01x³+1.30994E-01x²+2.25458E-01x−8.59463E-01 Equation 3

The straggling calculated by substituting the actual projected range Rp′ at the time of manufacturing the semiconductor device 100 into Equation 3 is defined as ΔRp. When an actual straggling ΔRp′ at the time of manufacture is within ±20% of the straggling ΔRp calculated from Equation 3, it may be considered that ³He is used. The actual straggling ΔRp′ preferably does not include helium diffusion due to thermal annealing. The actual straggling ΔRp′ may be a value measured after helium implantation and before the thermal annealing, or may be a value obtained by subtracting the helium diffusion from a value measured after the thermal annealing.

In ⁴He, the relationship between the projected range Rp and the straggling ΔRp may be given by Equation 4:

y=3.10234E-03x⁶−9.20762E-03x⁵−6.13612E-02x⁴+2.34304E-01x³+3.88591E-02x²+2.22955E-01x−8.01967E-01 Equation 4

When the actual straggling ΔRp′ at the time of manufacture is within ±20% of the straggling ΔRp calculated from Equation 4 by using the actual projected range Rp′, it may be considered that ⁴He is used. The actual straggling ΔRp′ preferably does not include the helium diffusion due to the thermal annealing.

As shown in FIG. 4C, when the projected range Rp is equal to or smaller than a boundary value with a value of a region where the projected range Rp is 10 to 20 μm being as the boundary value, the straggling ΔRp of ³He is approximately 10% smaller than the straggling ΔRp of ⁴He. When the projected range Rp is equal to or greater than the boundary value, the straggling ΔRp of ³He is substantially equal to the straggling ΔRp of ⁴He. This is presumed to be due to changes in a balance between an electronic stopping power and a nuclear stopping power depending on the number of neutrons of the isotope.

As an example, when the projected range Rp is 20 μm or less, ³He may be used. This can make the straggling ΔRp approximately 10% smaller. Alternatively, if a difference which is given to the helium chemical concentration distribution or electrical characteristics by a difference of approximately 10% in the straggling ΔRp is sufficiently small, also when the projected range Rp is 20 μm or less, it may be considered that the straggling ΔRp of ³He is substantially equal to the straggling ΔRp of ⁴He. In this case, helium atoms implanted into the semiconductor substrate 10 may be ³He, or may be ⁴He.

As an example, a full width at half maximum of the helium chemical concentration peak 221 when ⁴He is implanted is 1 μm or less. The full width at half maximum of the helium chemical concentration peak 221 may be 0.5 μm or less. A shape of a distribution of recombination center density peaks 220 can be easily controlled by arranging a plurality of helium chemical concentration peaks 221 with small half value widths in the buffer region 20. In addition, it is possible to suppress the hydrogen donors formed by implanting helium from being distributed over a wide range. Therefore, it is possible to suppress the doping concentration distribution of the buffer region 20 from varying over a wide range.

In addition, providing the plurality of helium chemical concentration peaks 221 can maintain a total concentration of the recombination center density peaks 220 high. Therefore, a carrier lifetime can be shortened and a tail current can be suppressed for example when the semiconductor device 100 is turned off.

It should be noted that, when the acceleration energy E of ³He is approximately 20 MeV or more (the projected range Rp is 270 μm or more), the straggling ΔRp is 10 μm or more. When the acceleration energy E of ⁴He is approximately 21 MeV or more (the projected range Rp is 250 μm or more), the straggling ΔRp is 10 μm or more. In this case, the full width at half maximum of the helium chemical concentration peak 221 cannot be made sufficiently smaller than a width of the buffer region 20 in the depth direction. Therefore, the hydrogen donors are formed over a wide range of the buffer region 20, and the doping concentration distribution varies. Therefore, an electric field may be locally concentrated when a short circuit occurs in the buffer region 20, to decrease short-circuit current tolerance. In contrast, decreasing a half value width of the helium chemical concentration peak 221 makes it easy to maintain the short-circuit current tolerance. Therefore, when either ³He or ⁴He is implanted, the acceleration energy E may be 20 MeV or less, or may be 10 MeV or less. Alternatively, the acceleration energy E of at least one or more or two or more helium chemical concentration peaks 221 of the plurality of helium chemical concentration peaks 221 may be 10 MeV or less, or may be 5 MeV or less.

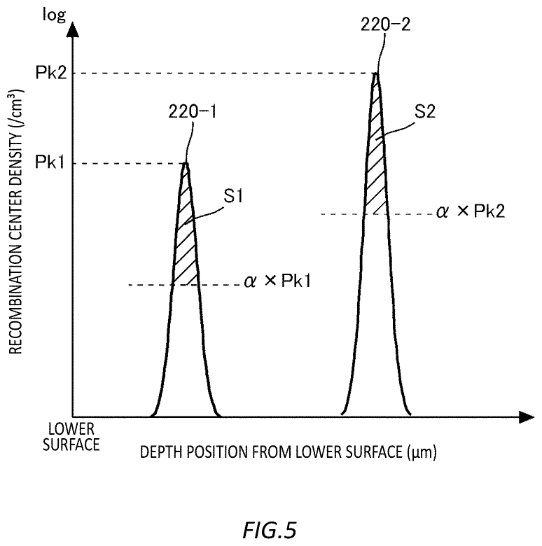

FIG. 5 illustrates a first recombination center density peak 220-1 and a second recombination center density peak 220-2. A peak value of the first recombination center density peak 220-1 is defined as Pk1, and a peak value of the second recombination center density peak 220-2 is defined as Pk2. An integrated value of the first recombination center density peak 220-1 in a depth direction is defined as S1, and an integrated value of the second recombination center density peak 220-2 in the depth direction is defined as S2. The integrated value S1 may be a value obtained by integrating a range where a recombination center density is equal to or greater than α×Pk1 (in FIG. 5, a range hatched with diagonal lines) at the first recombination center density peak 220-1. The coefficient α is a real number greater than 0 and smaller than 1. For example, when α=0.5, the integrated value S1 is a value obtained by integrating the first recombination center density peak 220-1 by a range of a full width at half maximum. Similarly, the integrated value S2 may be a value obtained by integrating a range where the recombination center density is equal to or greater than α×Pk2 at the second recombination center density peak 220-2. The coefficient α may be the same for each recombination center density peak 220. The coefficient α may be 0.5, may be 0.1, may be 0.01, or may be another numerical value. It should be noted that a distribution of recombination center densities may be calculated from a distribution of carrier lifetimes, or may be measured by another method. For the distribution of the recombination center densities, for example, a vacancy concentration measured by a positron annihilation method may be used as the recombination center density. Alternatively, an atomic density of helium atoms measured by an SIMS method may be used as the recombination center density.

The integrated value S2 of the second recombination center density peak 220-2 in this example is greater than the integrated value S1 of the first recombination center density peak 220-1. Each integrated value can be adjusted with a dose amount of a charged particle beam such as helium implanted at each depth position. Increasing the integrated value S2 can significantly reduce a reverse recovery loss Err. The integrated value S2 may be equal to or greater than twice, may be equal to or greater than five times, or may be equal to or greater than ten times, the integrated value S1.

The peak value Pk2 of the second recombination center density peak 220-2 in this example may be greater than the peak value Pk1 of the first recombination center density peak 220-1. At least one of a condition of the integrated value S2>the integrated value S1 or a condition of the peak value Pk2>the peak value Pk1 may be satisfied, or both may be satisfied. The peak value Pk2 may be equal to or greater than twice, may be equal to or greater than five times, or may be equal to or greater than ten times, the peak value Pk1.

The peak value of the first helium chemical concentration peak 221-1 may be smaller than the peak value of the second helium chemical concentration peak 221-2, may be the same as the peak value of the second helium chemical concentration peak 221-2, or may be greater than the peak value of the second helium chemical concentration peak 221-2. Recombination centers formed by radiating helium may be terminated with hydrogen to become hydrogen donors. Therefore, even when the peak value of the first helium chemical concentration peak 221-1 is the same as or greater than the peak value of the second helium chemical concentration peak 221-2, it is possible that the integrated value S2>the integrated value S1 or the peak value Pk2>the peak value Pk1 depending on a difference in a hydrogen concentration at each position.

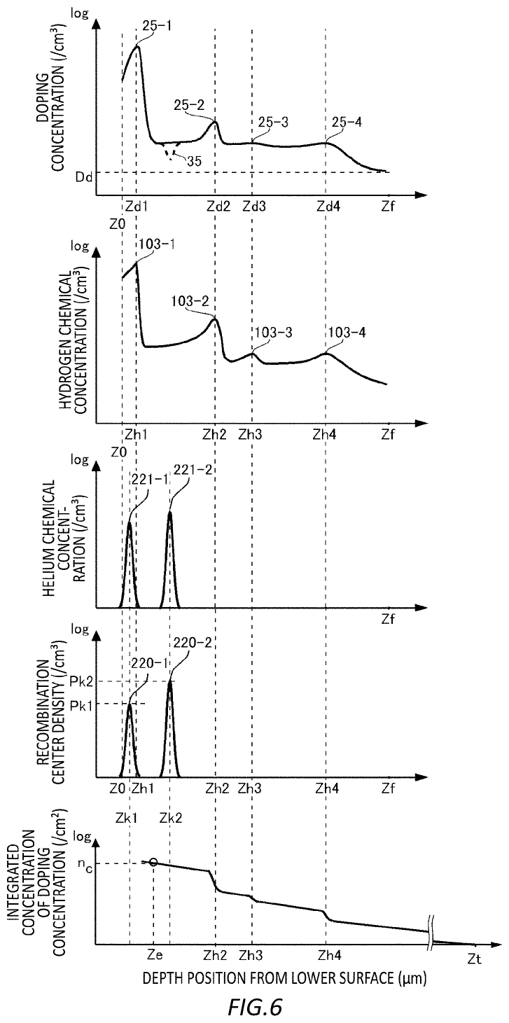

FIG. 6 illustrates examples of a doping concentration distribution, a hydrogen chemical concentration distribution, a helium chemical concentration distribution, a recombination center density distribution, and an integrated concentration distribution of a doping concentration in a buffer region 20. The concentration distributions may be similar to respective concentration distributions described with respect to FIG. 4A. The integrated concentration distribution in this example is a distribution of integrated values (/cm²) obtained by integrating the doping concentration from a lower end position Zt of a trench portion toward a lower surface 23. It should be noted that, when a P type layer is formed so as to include a lower end of the trench portion, the lower end position Zt may be defined as a position of a PN junction with a drift region 18 located at a lower surface 23 side of a semiconductor substrate 10 in the P type layer. That is, the integrated concentration distribution in this example may be defined as a distribution of integrated values (/cm²) obtained by integrating the doping concentration from the position of the PN junction with the drift region 18 located at the lower surface 23 side of the semiconductor substrate 10 in the P type layer toward the lower surface 23.

The doping concentration distribution in this example has one or more doping concentration peaks 25-1, 25-2, 25-3, and 25-4 in order starting from the lower surface 23 side of the semiconductor substrate 10. The doping concentration peak 25-1 is an example of the shallowest doping concentration peak which is closest to the lower surface 23 among the doping concentration peaks 25 of the buffer region 20. The doping concentration peak 25-4 is an example of the deepest doping concentration peak which is arranged farthest away from the lower surface 23. Depth positions of the respective doping concentration peaks 25 are defined as Zd1, Zd2, Zd3, and Zd4 in order starting from the lower surface 23 side. Each depth position Zd indicates a distance from the lower surface 23. It should be noted that any of the doping concentration peaks 25 may not be a clear peak. For example, an inflection point (a kink) of a slope of the doping concentration distribution may be defined as the doping concentration peak 25. The doping concentration peak 25-1 may be the doping concentration peak 25 having the greatest concentration value. The doping concentration peak 25-2 may be the doping concentration peak 25 having the second greatest concentration value. The doping concentration peak 25-3 may be the doping concentration peak 25 having the smallest concentration value. The doping concentration peak 25-4 may be the doping concentration peak 25 having a higher concentration than the doping concentration peak 25-3.

The hydrogen chemical concentration distribution in this example has hydrogen chemical concentration peaks 103-1, 103-2, 103-3, and 103-4 in order starting from the lower surface 23 side of the semiconductor substrate 10. Depth positions of the respective hydrogen chemical concentration peaks 103 are defined as Zh1, Zh2, Zh3, and Zh4 in order starting from the lower surface 23 side. Each depth position Zh indicates a distance from the lower surface 23. A depth position Zdk may be the same position as a depth position Zhk. Note that k is an integer of 1 to 4. The hydrogen chemical concentration peak 103-1 may be the hydrogen chemical concentration peak 103 having the greatest concentration value. The hydrogen chemical concentration peak 103-2 may be hydrogen chemical concentration peak 103 having the second greatest concentration value. The hydrogen chemical concentration peak 103-3 may be the hydrogen chemical concentration peak 103 having the smallest concentration value. The hydrogen chemical concentration peak 103-4 may be the hydrogen chemical concentration peak 103 having a higher concentration than the hydrogen chemical concentration peak 103-3.

The helium chemical concentration distribution in this example has a first helium chemical concentration peak 221-1 and a second helium chemical concentration peak 221-2 in order starting from the lower surface 23 side of the semiconductor substrate 10. The recombination center density distribution in this example has a first recombination center density peak 220-1 and a second recombination center density peak 220-2 in order starting from the lower surface 23 side of the semiconductor substrate 10. Depth positions of the respective helium chemical concentration peaks 221 are defined as Zk1 and Zk2 in order starting from the lower surface 23 side. Depth positions of the respective recombination center density peaks 220 may be defined as Zk1 and Zk2 in order starting from the lower surface 23 side. Each depth position Zk indicates a distance from the lower surface 23.

The first recombination center density peak 220-1 is arranged between any of the doping concentration peaks 25 and the lower surface 23 of the semiconductor substrate 10, and the second recombination center density peak 220-2 is arranged between the doping concentration peak 25 and an upper surface 21. The first recombination center density peak 220-1 in this example is arranged on the lower surface 23 side relative to the doping concentration peak 25-1, and the second recombination center density peak 220-2 is arranged on an upper surface 21 side relative to the doping concentration peak 25-1. In a more specific example, the second recombination center density peak 220-2 is arranged between the doping concentration peak 25-1 and the doping concentration peak 25-2. In another example, the second recombination center density peak 220-2 may be arranged between the doping concentration peak 25-2 and the doping concentration peak 25-3, or may be arranged between the doping concentration peak 25-3 and the doping concentration peak 25-4. That is, only one doping concentration peak 25 may be arranged or a plurality of doping concentration peaks 25 may be arranged between the first recombination center density peak 220-1 and the second recombination center density peak 220-2. As described below, arranging the first recombination center density peak 220-1 on the lower surface 23 side relative to the doping concentration peak 25-1 can suppress a reverse recovery loss while suppressing a leakage current. In addition, arranging the second recombination center density peak 220-2 on the upper surface 21 side relative to the doping concentration peak 25-1 can significantly reduce the reverse recovery loss.

It should be noted that, when a carrier concentration distribution measured by an SRP method is the doping concentration distribution, the doping concentration distribution may have a valley portion 35 at the same depth position as that of any of the helium chemical concentration peaks 221. The valley portion 35 is a region where the doping concentration shows a local minimum value. In this example, since a recombination center density peak 220 is provided at the same depth position as that of a helium chemical concentration peak 221, carrier mobility at the position decreases. This decreases a carrier concentration as described above. In the subsequent drawings showing doping concentration distributions, valley portions 35 are omitted at the same depth positions as those of the helium chemical concentration peaks 221, but the valley portions 35 may be provided.

A depletion layer edge position Ze is a depth position at which an integrated concentration obtained by integrating net doping concentrations of the drift region 18 and the buffer region 20 from an upper end of the drift region 18 toward the lower surface 23 of the semiconductor substrate 10 reaches a critical integrated concentration nc. The depletion layer edge position Ze may be referred to as a critical concentration depth position Ze. In the present specification, if a forward bias is applied between a collector electrode 24 and an emitter electrode 52 and an avalanche breakdown occurs, when an area from the upper end of the drift region 18 to a specific position in the buffer region 20 is depleted, a value obtained by integrating the net doping concentration from the upper end of the drift region 18 to the specific position is referred to as a critical integrated concentration. That is, the depletion layer edge position Ze is a position which is closest to the lower surface 23 reached by a depletion layer expanding from a lower end of a base region 14 toward the lower surface 23 of the semiconductor substrate 10 when the avalanche breakdown occurs. The critical integrated concentration nc depends on constituent atoms of the semiconductor substrate 10. When the semiconductor substrate 10 is made of silicon, the critical integrated concentration nc is about 1.2×10¹²/cm². The position which is closest to the lower surface 23 reached by the depletion layer when a rated voltage of the semiconductor device 100 is applied between the collector electrode 24 and the emitter electrode 52 may be defined as the depletion layer edge position Ze. Arranging the depletion layer edge position Ze in the buffer region 20 can prevent the depletion layer from reaching a collector region 22 or a cathode region 82.

It should be noted that the upper end of the drift region 18 is a boundary position between the drift region 18 and an accumulation region 16 in the example shown in FIG. 3. When it is difficult to determine the boundary position between the drift region 18 and the accumulation region 16, the lower end position Zt of the trench portion may be defined as a lower end of the drift region 18. In addition, when the drift region 18 is in contact with the base region 14, a position of a PN junction at a boundary between the drift region 18 and the base region 14 is the upper end of the drift region 18.

The depletion layer edge position Ze may be located between the first recombination center density peak 220-1 and the second recombination center density peak 220-2. The depletion layer edge position Ze may be located between the doping concentration peak 25-1 and the doping concentration peak 25-2. An integrated value of a recombination center density on the upper surface 21 side relative to the critical concentration depth position Ze may be greater than, may be equal to, or may be smaller than, an integrated value of a recombination center density on the lower surface 23 side relative to the critical concentration depth position Ze. In this example, the integrated value of the recombination center density on the upper surface 21 side relative to the critical concentration depth position Ze is greater than the integrated value of the recombination center density on the lower surface 23 side relative to the critical concentration depth position Ze. An integrated value of a helium chemical concentration on the upper surface 21 side relative to the critical concentration depth position Ze may be greater than, may be equal to, or may be smaller than, an integrated value of a helium chemical concentration on the lower surface 23 side relative to the critical concentration depth position Ze. In this example, the integrated value of the helium chemical concentration on the upper surface 21 side relative to the critical concentration depth position Ze is greater than the integrated value of the helium chemical concentration on the lower surface 23 side relative to the critical concentration depth position Ze.

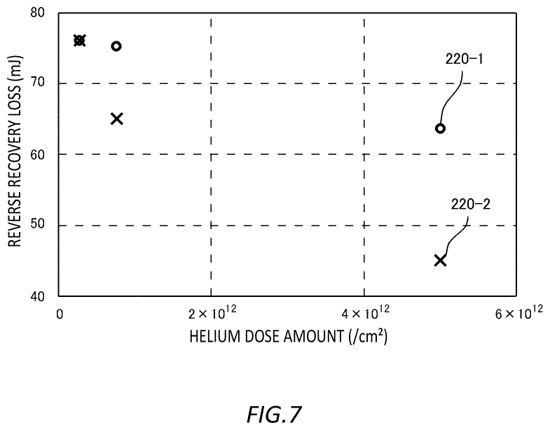

FIG. 7 illustrates relationships between helium dose amounts at a first recombination center density peak 220-1 and a second recombination center density peak 220-2, and a reverse recovery loss Err. Arrangement of the first recombination center density peak 220-1 and the second recombination center density peak 220-2 is similar to that in the example shown in FIG. 4A.

Increasing a helium dose amount increases an integrated value S and a peak value Pk of each recombination center density peak 220. The reverse recovery loss Err refers to a loss during reverse recovery of a diode portion 80. In FIG. 7, circle marks indicate results of changing the helium dose amount of the first recombination center density peak 220-1 while maintaining the helium dose amount for the second recombination center density peak 220-2, and X marks indicate results of changing the helium dose amount of the second recombination center density peak 220-2 while maintaining the helium dose amount for the first recombination center density peak 220-1.

At each recombination center density peaks 220, increasing the helium dose amount increases a recombination center density. Therefore, a carrier lifetime during the reverse recovery of the diode portion 80 is shortened, and the reverse recovery loss decreases. Especially, since a recombination center is formed in a buffer region 20, a tail current flowing during the reverse recovery of the diode portion 80 can be decreased, or a time period when the tail current flows can be shortened. Therefore, the reverse recovery loss can be decreased. As shown in FIG. 7, the reverse recovery loss can be significantly reduced by increasing the helium dose amount for the second recombination center density peak 220-2 more than for the first recombination center density peak 220-1. It can be assumed that this is because, in the time period when the tail current flows through the diode portion 80 during the reverse recovery, many carriers remain on an upper surface 21 side relative to a doping concentration peak 25-1, and thus increasing an integrated value of the second recombination center density peak 220-2 can efficiently decrease the tail current and also shorten the time period when the tail current flows. Therefore, the reverse recovery loss can be significantly reduced by making an integrated value S2 or a peak value Pk2 of the second recombination center density peak 220-2 greater than an integrated value S1 or a peak value Pk1 of the first recombination center density peak 220-1.

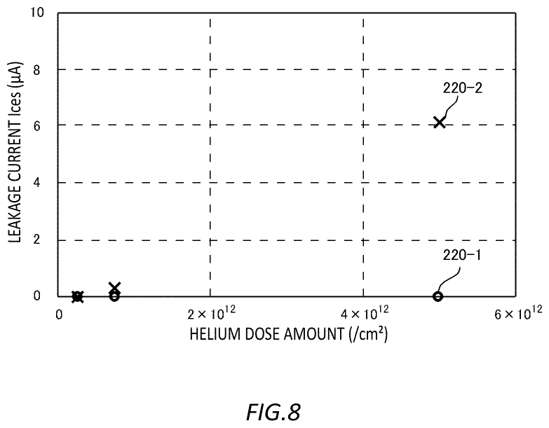

FIG. 8 illustrates relationships between helium dose amounts at a first recombination center density peak 220-1 and a second recombination center density peak 220-2, and a leakage current Ices. Arrangement of the first recombination center density peak 220-1 and the second recombination center density peak 220-2 is similar to that in the example shown in FIG. 4A. Measurement conditions in plots of circle marks and X marks in FIG. 8 are similar to those in the example shown in FIG. 7.

The leakage current Ices is also referred to as a collector-emitter breaking current. The leakage current Ices is a leakage current between a collector and an emitter for when a predetermined voltage is applied between the collector and the emitter while a gate and the emitter are short-circuited (that is, a transistor portion 70 is in an off state). Forming a recombination center in a semiconductor substrate 10 may increase the leakage current via the recombination center.

As shown in FIG. 8, increasing a helium dose amount of the second recombination center density peak 220-2 tends to increase the leakage current Ices. On the other hand, even increasing a helium dose amount of the first recombination center density peak 220-1 hardly increases the leakage current Ices. Therefore, providing the first recombination center density peak 220-1 can reduce a reverse recovery loss Err while suppressing an increase in the leakage current Ices. As described above, appropriately adjusting a ratio of integrated values of the first recombination center density peak 220-1 and the second recombination center density peak 220-2 can significantly reduce the reverse recovery loss while suppressing the increase in the leakage current Ices.

On the other hand, a buffer region 20 may be provided in both a diode portion 80 and the transistor portion 70. An integrated value S1 of the first recombination center density peak 220-1 in the diode portion 80 may be the same as an integrated value S1 of the first recombination center density peak 220-1 in the transistor portion 70. A structure of the buffer region 20 in the diode portion 80 may be the same as a structure of the buffer region 20 in the transistor portion 70. In this case, making the integrated value S1 or a peak value Pk1 of the first recombination center density peak 220-1 too great inhibits carrier injection from a collector region 22 of the transistor portion 70, lowers a carrier injection enhancement effect (IE effect), and increases an on-voltage of the transistor portion 70. In contrast, making the integrated value S1 or the peak value Pk1 of the first recombination center density peak 220-1 smaller than an integrated value S2 or a peak value Pk2 of the second recombination center density peak 220-2 can suppress an increase in the on-voltage of the transistor portion 70 while improving a characteristic of the diode portion 80.

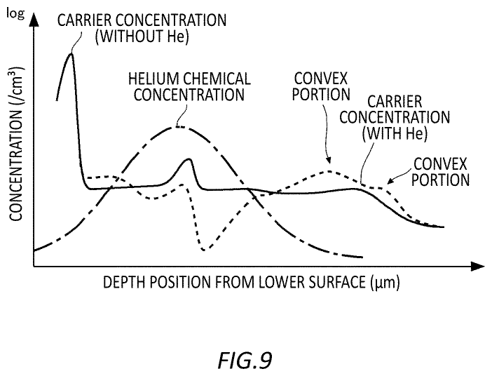

FIG. 9 shows examples of a carrier concentration distribution and a helium chemical concentration distribution in a buffer region 20 according to a comparative example. The buffer region 20 in this example has only one peak of the helium chemical concentration formed by implanting ³He. In addition, in FIG. 9, the carrier concentration distribution when helium is not implanted is indicated by a solid line, and the carrier concentration distribution when helium is implanted is indicated by a broken line. The carrier concentration distribution when helium is not implanted is similar to the doping concentration distribution in FIG. 6 or the like.

In this example, a single peak of the helium chemical concentration is provided in the buffer region 20. Therefore, it is difficult to control a distribution of lifetime killers. In addition, when a half value width of a helium chemical concentration peak is great, hydrogen donors in which recombination centers and hydrogen are attached together are distributed over a wide range, and the carrier concentration distribution varies over a wider range than when helium is not implanted. Especially, when a distribution of helium spreads to the vicinity of an upper end of the buffer region 20, a convex portion appears in the carrier concentration distribution, and the characteristic of the semiconductor device 100 may deviate from a designed value, such as a decrease in an avalanche capability. In contrast, in the examples shown in FIG. 1 to FIG. 8, since a plurality of helium chemical concentration peaks are arranged in the buffer region 20, the distribution of the lifetime killers can be precisely adjusted. In addition, decreasing the half value width of the helium chemical concentration peak can suppress a variation of the carrier concentration distribution over a wide range.

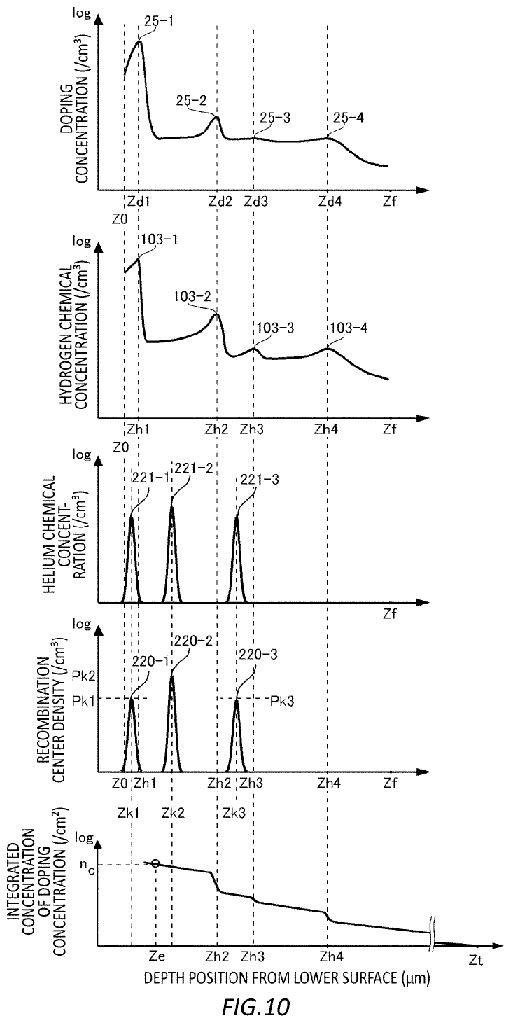

FIG. 10 illustrates other examples of a doping concentration distribution, a hydrogen chemical concentration distribution, a helium chemical concentration distribution, a recombination center density distribution, and an integrated concentration distribution of a doping concentration in a buffer region 20. The buffer region 20 in this example is different from the buffer region 20 described with respect to FIG. 1 to FIG. 9 in that it further includes a third helium chemical concentration peak 221-3 and a third recombination center density peak 220-3. Other structures are similar to those of the buffer region 20 according to any of the aspects described with respect to FIG. 1 to FIG. 9. The third helium chemical concentration peak 221-3 and the third recombination center density peak 220-3 are arranged at a depth position Zk3. A peak value of the third recombination center density peak 220-3 is defined as Pk3.

The third recombination center density peak 220-3 is arranged farther away from a lower surface 23 of a semiconductor substrate 10 than a second recombination center density peak 220-2. An integrated value S2 of the second recombination center density peak 220-2 in a depth direction is greater than an integrated value S3 of the third recombination center density peak 220-3 in the depth direction. The integrated value S3 is a value obtained by integrating a range where a recombination center density is equal to or greater than α×Pk3 at the third recombination center density peak 220-3, similarly to the example described with respect to FIG. 5. The coefficient α may be the same as those of other recombination center density peaks 220.

There is a tendency that the farther a recombination center density peak 220 is located away from the lower surface 23, the greater a reduction width of a reverse recovery loss Err is when an integrated value S is increased. Therefore, providing the third recombination center density peak 220-3 can further reduce the reverse recovery loss Err. On the other hand, excessively increasing the integrated value S of the recombination center density peak 220 located away from the lower surface 23 may enhance formation of hydrogen donors and generate a convex portion in a carrier density distribution in the vicinity of an upper end of the buffer region 20 as described with respect to FIG. 9. In contrast, making the integrated value S3 of the third recombination center density peak 220-3 smaller than the integrated value S2 of the second recombination center density peak 220-2 can suppress generation of the convex portion in the carrier density distribution while efficiently reducing the reverse recovery loss Err. The integrated value S2 may be equal to or greater than twice, may be equal to or greater than five times, or may be equal to or greater than ten times, the integrated value S3.

The peak value Pk2 of the second recombination center density peak 220-2 may be greater than the peak value Pk3 of the third recombination center density peak 220-3. At least one of a condition of the integrated value S2>the integrated value S3 or a condition of the peak value Pk2>the peak value Pk3 may be satisfied, or both may be satisfied. The peak value Pk2 may be equal to or greater than twice, may be equal to or greater than five times, or may be equal to or greater than ten times, the peak value Pk3.

The peak value Pk2 of the second recombination center density peak 220-2 may be greater than both a peak value Pk1 of a first recombination center density peak 220-1 and the peak value Pk3 of the third recombination center density peak 220-3. The integrated value S2 of the second recombination center density peak 220-2 may be greater than both an integrated value S1 of the first recombination center density peak 220-1 and the integrated value S3 of the third recombination center density peak 220-3.

Either of the integrated value S1 of the first recombination center density peak 220-1 and the integrated value S3 of the third recombination center density peak 220-3 may be greater than the other, or they may be the same. Either of the peak value Pk1 of the first recombination center density peak 220-1 and the peak value Pk3 of the third recombination center density peak 220-3 may be greater than the other, or they may be the same.

The buffer region 20 in this example has three or more doping concentration peaks 25. The second recombination center density peak 220-2 may be arranged between any two doping concentration peaks. In the example shown in FIG. 10, the second recombination center density peak 220-2 is arranged between a doping concentration peak 25-1 and a doping concentration peak 25-2. The third recombination center density peak 220-3 may be arranged between any two doping concentration peaks 25 which are different from those in a case of the second recombination center density peak 220-2. In the example shown in FIG. 10, the third recombination center density peak 220-3 is arranged between the doping concentration peak 25-2 and a doping concentration peak 25-3. That is, only one doping concentration peak 25 may be arranged between the second recombination center density peak 220-2 and the third recombination center density peak 220-3. In another example, a plurality of doping concentration peaks 25 may be arranged between the second recombination center density peak 220-2 and the third recombination center density peak 220-3.

In this example, a doping concentration peak 25-4 arranged farthest away from the lower surface 23 of the semiconductor substrate 10 is defined as a first upper surface-side doping concentration peak, and the doping concentration peak 25-3 adjacent to the doping concentration peak 25-4 in the depth direction is defined as a second upper surface-side doping concentration peak. That is, the doping concentration peak 25-4 and the doping concentration peak 25-3 are two doping concentration peaks arranged closest to an upper surface 21 in the buffer region 20.

The third recombination center density peak 220-3 may be arranged on a lower surface 23 side of the semiconductor substrate 10 relative to the second upper surface-side doping concentration peak (the doping concentration peak 25-3). The recombination center density peak 220 may not be arranged between the first upper surface-side doping concentration peak (the doping concentration peak 25-4) and the second upper surface-side doping concentration peak (the doping concentration peak 25-3). Such a configuration can suppress generation of the convex portion (see FIG. 9) in the carrier concentration distribution in the vicinity of the upper end of the buffer region 20.

A helium chemical concentration peak 221 may be considered as the recombination center density peak 220. A helium chemical concentration in the buffer region 20 may be treated as the recombination center density in the buffer region 20. In each example shown in the present specification, the integrated value S1 of the first helium chemical concentration peak 221-1 may be 1×10¹¹ (/cm²) or more and 1×10¹² (/cm²) or less. In each example shown in the present specification, the integrated value S2 of the second helium chemical concentration peak 221-2 may be 1×10¹¹ (/cm²) or more and 1×10¹² (/cm²) or less. In each example shown in the present specification, the integrated value S3 of the third helium chemical concentration peak 221-3 may be 1×10¹⁰ (/cm²) or more and 1×10¹¹ (/cm²) or less. Even when ranges of integrated values of respective peaks are the same or overlap, the integrated values of the respective peaks may be different. Within the ranges of the integrated values of the respective peaks, the integrated value S2 of the second helium chemical concentration peak 221-2 may be greater than the integrated value S1 of the first helium chemical concentration peak 221-1. Within the ranges of the integrated values of the respective peaks, the integrated value S2 of the second helium chemical concentration peak 221-2 may be greater than the integrated value S3 of the third helium chemical concentration peak 221-3.

A dose amount of helium ions for the first helium chemical concentration peak 221-1 may be 1×10¹¹ ions/cm² or more and 1×10¹² ions/cm² or less. A dose amount of helium ions for the second helium chemical concentration peak 221-2 may be 1×10¹¹ ions/cm² or more and 1×10¹² ions/cm² or less. A dose amount of helium ions for the third helium chemical concentration peak 221-3 may be 1×10¹⁰ ions/cm² or more and 1×10¹¹ ions/cm² or less. The buffer region 20 may further have a fourth helium chemical concentration peak on an upper surface 21 side relative to the third helium chemical concentration peak 221-3. An integrated value of the fourth helium chemical concentration peak is smaller than the integrated value of the third helium chemical concentration peak 221-3. A dose amount of helium ions for the fourth helium chemical concentration peak may be 0.5×10¹⁰ ions/cm² or more and 5×10¹⁰ ions/cm² or less.

In each example shown in the present specification, the peak value Pk1 of the first helium chemical concentration peak 221-1 may be 1×10¹⁵ (/cm³) or more and 1×10¹⁷ (/cm³) or less. In each example shown in the present specification, the peak value Pk2 of the second helium chemical concentration peak 221-2 may be 1×10¹⁵ (/cm³) or more and 1×10¹⁷ (/cm³) or less. In each example shown in the present specification, the peak value Pk3 of the third helium chemical concentration peak 221-3 may be 1×10¹⁴ (/cm³) or more and 1×10¹⁶ (/cm³) or less. A full width at half maximum of the second helium chemical concentration peak 221-2 may be greater than a full width at half maximum of the first helium chemical concentration peak 221-1. In this case, the integrated value S2 of the second helium chemical concentration peak 221-2 may be greater than the integrated value S1 of the first helium chemical concentration peak 221-1, or the peak value Pk2 of the second helium chemical concentration peak 221-2 may be smaller than the peak value Pk1 of the first helium chemical concentration peak 221-1.

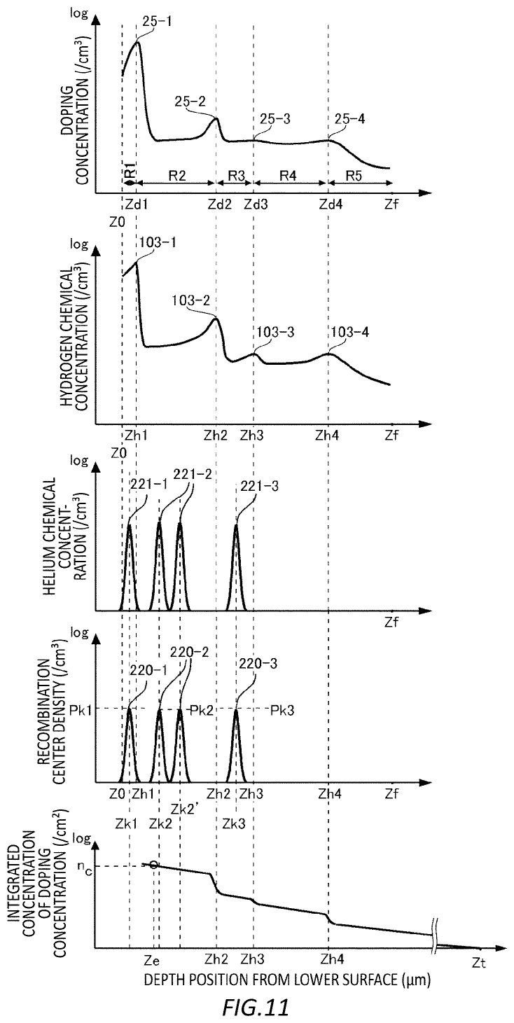

FIG. 11 describes inter-peak regions in a buffer region 20. A doping concentration distribution, a hydrogen chemical concentration distribution, a helium chemical concentration distribution, a recombination center density distribution, and an integrated concentration distribution of a doping concentration in the buffer region 20 may be the same as or different from those in the examples shown in FIG. 1 to FIG. 10. In this example, a region between a lower surface 23 of a semiconductor substrate 10 and a doping concentration peak 25-1 (R1), a region between two doping concentration peaks 25 which are adjacent to each other in a depth direction (R2 to R4), and a region between a doping concentration peak 25-4 and a drift region 18 (R5) are referred to as the inter-peak regions.

The buffer region 20 in this example has the first inter-peak region R1 provided with one or more first recombination center density peaks 220-1 and the second inter-peak region R2 provided with one or more second recombination center density peaks 220-2. The second inter-peak region R2 is arranged farther away from the lower surface 23 of the semiconductor substrate 10 than the first inter-peak region R1. The second inter-peak region R2 may be arranged next to the first inter-peak region R1.

An integrated value S2′ of a recombination center density of the second inter-peak region R2 in the depth direction is greater than an integrated value S1′ of a recombination center density of the first inter-peak region R1 in the depth direction. As in the example shown in FIG. 4A or the like, when a single recombination center density peak 220 is arranged in each inter-peak region, an integrated value in each inter-peak region is an integrated value of the recombination center density peak 220.

As shown in FIG. 11, a plurality of recombination center density peaks 220 may be provided in any of the inter-peak regions. In the example shown in FIG. 11, two second recombination center density peaks 220-2 are provided in the second inter-peak region R2. In this case, the integrated value S2′ in the second inter-peak region R2 is a sum of integrated values S2 of the two second recombination center density peaks 220-2. A relationship between the integrated value S2′ and the integrated value S1′ may be the same as a relationship between the integrated value S2 and the integrated value S1 described with respect to FIG. 1 to FIG. 10.

Integrated values S2 of respective second recombination center density peaks 220-2 may be different from each other, or may be the same. An integrated value S2 of one second recombination center density peak 220-2 may be smaller than, may be the same as, or may be greater than, an integrated value S1 of one first recombination center density peak 220-1. An integrated value S2 of one second recombination center density peak 220-2 may be smaller than, may be the same as, or may be greater than, an integrated value S3 of one third recombination center density peak 220-3.

The buffer region 20 in this example may have the third inter-peak region R3 provided with one or more third recombination center density peaks 220-3. The third inter-peak region R3 is arranged farther away from the lower surface 23 of the semiconductor substrate 10 than the second inter-peak region R2. The third inter-peak region R3 may be arranged next to the second inter-peak region R2.

The integrated value S2′ of the recombination center density of the second inter-peak region R2 in the depth direction is greater than an integrated value S3′ of a recombination center density of the third inter-peak region R3 in the depth direction. A relationship between the integrated value S2′ and the integrated value S3′ may be the same as a relationship between the integrated value S2 and the integrated value S3 described with respect to FIG. 1 to FIG. 10. A relationship between the integrated value S1′ and the integrated value S3′ may be the same as a relationship between the integrated value S1 and the integrated value S3 described with respect to FIG. 1 to FIG. 10.

Such a configuration can also reduce a reverse recovery loss Err while suppressing an increase in a leakage current Ices, similarly to the examples described with respect to FIG. 1 to FIG. 10. The number of second recombination center density peaks 220-2 provided in the second inter-peak region R2 may be greater than the number of first recombination center density peaks 220-1 provided in the first inter-peak region R1. The number of second recombination center density peaks 220-2 provided in the second inter-peak region R2 may be greater than the number of third recombination center density peaks 220-3 provided in the third inter-peak region R3.

Positions of the first inter-peak region R1, the second inter-peak region R2, and the third inter-peak region R3 respectively provided with a first recombination center density peak 220-1, a second recombination center density peak 220-2, and a third recombination center density peak 220-3 are similar to those in any of the aspects described with respect to FIG. 1 to FIG. 10. In the example shown in FIG. 11, the first inter-peak region R1, the second inter-peak region R2, and the third inter-peak region R3 are arranged adjacent to each other, but they may be arranged away from each other.

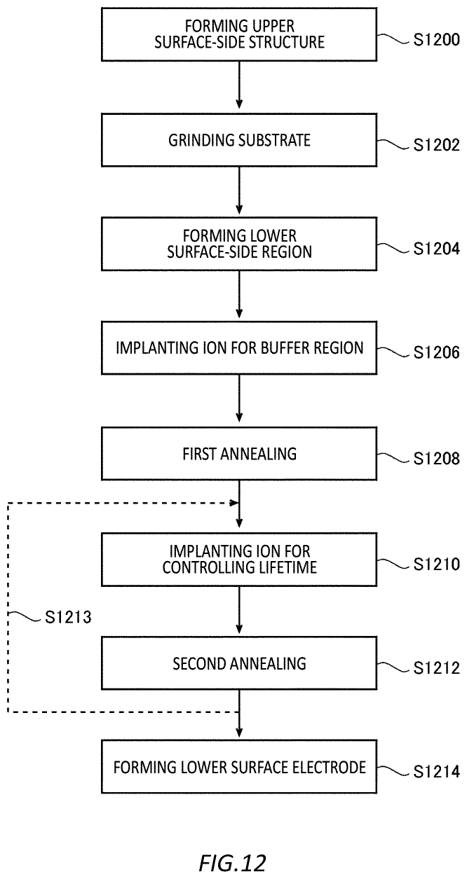

FIG. 12 illustrates some processes in a method for manufacturing a semiconductor device 100. In this example, in an upper surface-side structure formation step S1200, a structure on an upper surface 21 side of a semiconductor substrate 10 is formed. The structure on the upper surface 21 side may include at least one of doped regions, such as an emitter region 12, a base region 14, and an accumulation region 16, on the upper surface 21 side of the semiconductor substrate 10. The structure on the upper surface 21 side may include each trench portion. The structure on the upper surface 21 side may include a structure, such as an emitter electrode 52, above an upper surface 21 of the semiconductor substrate 10. The structure on the upper surface 21 side may include an edge termination structure portion 90.

Next, in a substrate grinding step S1202, a lower surface 23 of the semiconductor substrate 10 is ground to thin the semiconductor substrate 10. In S1202, the semiconductor substrate 10 may be thinned to a thickness corresponding to a breakdown voltage to be possessed by the semiconductor device 100.

Next, in a lower surface-side region formation step S1204, a lower surface doped region of the semiconductor substrate 10 is formed. The lower surface doped region is a doped region in contact with an electrode, such as the collector electrode 24 formed in a later process, formed on the lower surface 23. The lower surface doped region may include at least one of a cathode region 82 and a collector region 22.

Next, in a first ion implantation step S1206, ions for forming a buffer region 20 are implanted into the semiconductor substrate 10. In S1206, ions may be implanted from the lower surface 23 of the semiconductor substrate 10 into a region where the buffer region 20 is to be formed. In S1206, donor ions such as hydrogen ions (for example, protons) or phosphorous ions may be implanted.

Next, in a first annealing step S1208, the semiconductor substrate 10 is thermally annealed. In S1208, the semiconductor substrate 10 may be put into an electric furnace to anneal an entirety of the semiconductor substrate 10 (or a wafer). Annealing temperature in S1208 may be 320 degrees C. or higher and 420 degrees C. or lower. In S1208, annealing may be performed in an atmosphere containing hydrogen and nitrogen.

Next, in a second ion implantation step S1210, ions for forming a recombination center density peak 220 are implanted into the semiconductor substrate 10. In S1210, the ions may be implanted from the lower surface 23 of the semiconductor substrate 10. In S1210, hydrogen ions such as protons or helium ions may be implanted. In this example, the helium ions are implanted.

In S1210, the recombination center density peak 220 described with respect to FIG. 4A to FIG. 11 is formed. Sequentially changing acceleration energy of the helium ions or the like can form recombination center density peaks 220 at a plurality of positions in a depth direction. In S1210, the helium ions or the like may be implanted in order starting from a position closest to the lower surface 23 among the plurality of positions in the depth direction, or the helium ions or the like may be implanted in order starting from a position farthest from the lower surface 23. In this example, the helium ions are implanted in order starting from the position farthest from the lower surface 23. In addition, in S1210, ion implantation may be performed in order starting from the recombination center density peak 220 with the greatest dose amount, or ion implantation may be performed in order starting from the recombination center density peak 220 with the smallest dose amount.

Next, in a second annealing step S1212, the semiconductor substrate 10 is thermally annealed. In S1212, the semiconductor substrate 10 may be put into an electric furnace to anneal the entirety of the semiconductor substrate 10 (or the wafer). Annealing temperature in S1212 may be lower than the annealing temperature in S1208. The annealing temperature in S1212 may be 300 degrees C. or higher and 400 degrees C. or lower. In S1212, annealing may be performed in a nitrogen atmosphere or the atmosphere containing hydrogen and nitrogen.

S1212 may be performed each time the helium ions or the like are implanted at one depth position in S1210, or may be performed each time the helium ions or the like are implanted at a plurality of depth positions. A set of processes of S1210 and S1212 may be repeated a plurality of times (S1213).

Next, in a lower surface electrode formation step S1214, an electrode in contact with the lower surface 23 is formed. In S1214, the collector electrode 24 may be formed. Such processes can form the semiconductor device 100.

While the present invention has been described with the embodiments, the technical scope of the present invention is not limited to the above-described embodiments. It is apparent to persons skilled in the art that various alterations and improvements can be added to the above-described embodiments. It is also apparent from the description of the claims that embodiments added with such alterations or improvements can be included in the technical scope of the present invention.

The operations, procedures, steps, and stages of each process performed by an apparatus, system, program, and method illustrated in the claims, embodiments, or diagrams can be performed in any order as long as the order is not indicated by “prior to,” “before,” or the like and as long as the outputted from a previous process is not used in a later process. Even if the operation flow is described by using phrases such as “first” or “next” in the scope of the claims, specification, or drawings, it does not necessarily mean that the process must be performed in this order.

What is claimed is:

1. A semiconductor device comprising:
a semiconductor substrate having an upper surface and a lower surface and having a drift region of a first conductivity type; and
a buffer region of the first conductivity type provided between the drift region and the lower surface of the semiconductor substrate and having a higher doping concentration than the drift region, wherein
the buffer region has:
a first recombination center density peak; and
a second recombination center density peak arranged on a side of the upper surface of the semiconductor substrate relative to the first recombination center density peak, and
an integrated value of the second recombination center density peak in a depth direction is greater than an integrated value of the first recombination center density peak in the depth direction.

2. The semiconductor device according to claim 1, wherein
the buffer region has a third recombination center density peak arranged farther away from the lower surface of the semiconductor substrate than the second recombination center density peak, and
the integrated value of the second recombination center density peak in the depth direction is greater than an integrated value of the third recombination center density peak in the depth direction.

3. The semiconductor device according to claim 2, wherein
a peak value of the second recombination center density peak is greater than both a peak value of the first recombination center density peak and a peak value of the third recombination center density peak.

4. The semiconductor device according to claim 2, wherein
the buffer region has one or more doping concentration peaks in the depth direction of the semiconductor substrate,
the first recombination center density peak is arranged between any of the doping concentration peaks and the lower surface of the semiconductor substrate, and
the second recombination center density peak is arranged between the any of the doping concentration peaks and the upper surface of the semiconductor substrate.

5. The semiconductor device according to claim 4, wherein
the one or more doping concentration peaks include a shallowest doping concentration peak closest to the lower surface of the semiconductor substrate,
the first recombination center density peak is arranged between the shallowest doping concentration peak and the lower surface of the semiconductor substrate, and
the second recombination center density peak is arranged between the shallowest doping concentration peak and the upper surface of the semiconductor substrate.

6. The semiconductor device according to claim 5, wherein
the buffer region has three or more doping concentration peaks including the doping concentration peak,
the second recombination center density peak is arranged between any two of the doping concentration peaks, and
the third recombination center density peak is arranged between any two of the doping concentration peaks which are different from those in a case of the second recombination center density peak.

7. The semiconductor device according to claim 6, wherein
the three or more doping concentration peaks include:
a first upper surface-side doping concentration peak arranged farthest away from the lower surface of the semiconductor substrate; and
a second upper surface-side doping concentration peak adjacent to the first upper surface-side doping concentration peak in the depth direction, and
the third recombination center density peak is arranged on a side of the lower surface of the semiconductor substrate relative to the second upper surface-side doping concentration peak.

8. The semiconductor device according to claim 7, wherein
a recombination center density peak is not arranged between the first upper surface-side doping concentration peak and the second upper surface-side doping concentration peak.

9. The semiconductor device according to claim 4, wherein
the doping concentration peak is a concentration peak of hydrogen donors.

10. The semiconductor device according to claim 4, wherein
the doping concentration peak closest to the lower surface is a concentration peak of phosphorous, and
the doping concentration peak other than the doping concentration peak closest to the lower surface is a concentration peak of hydrogen donors.

11. The semiconductor device according to claim 1, wherein
a transistor portion and a diode portion are arrayed side by side in an array direction in the semiconductor substrate, and
the diode portion has the buffer region.

12. The semiconductor device according to claim 11, wherein
the transistor portion has the buffer region, and
the integrated value of the first recombination center density peak in the diode portion is the same as the integrated value of the first recombination center density peak in the transistor portion.

13. The semiconductor device according to claim 2, wherein
the first recombination center density peak is a first helium chemical concentration peak,
the second recombination center density peak is a second helium chemical concentration peak, and
the third recombination center density peak is a third helium chemical concentration peak.

14. The semiconductor device according to claim 13, wherein
an integrated value of the second helium chemical concentration peak in the depth direction is 1×10¹¹ (/cm²) or more and 1×10¹² (/cm²) or less.

15. The semiconductor device according to claim 14, wherein
an integrated value of the first helium chemical concentration peak in the depth direction is 1×10¹¹ (/cm²) or more and 1×10¹² (/cm²) or less.

16. The semiconductor device according to claim 15, wherein
an integrated value of the third helium chemical concentration peak in the depth direction is 1×10¹⁰ (/cm²) or more and 1×10¹¹ (/cm²) or less.

17. A semiconductor device comprising:
a semiconductor substrate having an upper surface and a lower surface and having a drift region of a first conductivity type; and
a buffer region of the first conductivity type provided between the drift region and the lower surface of the semiconductor substrate and having a higher doping concentration than the drift region, wherein
the buffer region has:
two or more doping concentration peaks provided at different positions in a depth direction, the two or more doping concentration peaks including a shallowest doping concentration peak arranged closest to the lower surface of the semiconductor substrate; and
a plurality of inter-peak regions provided between the lower surface of the semiconductor substrate and the shallowest doping concentration peak and between two of the doping concentration peaks adjacent to each other in the depth direction,
the plurality of inter-peak regions include:
a first inter-peak region provided with one or more first recombination center density peaks; and
a second inter-peak region arranged farther away from the lower surface of the semiconductor substrate than the first inter-peak region and provided with one or more second recombination center density peaks, and
an integrated value of a recombination center density of the second inter-peak region in the depth direction is greater than an integrated value of a recombination center density of the first inter-peak region in the depth direction.

18. The semiconductor device according to claim 17, wherein
the first recombination center density peak is a first helium chemical concentration peak,
the second recombination center density peak is a second helium chemical concentration peak, and
an integrated value of the second helium chemical concentration peak in the depth direction is greater than an integrated value of the first helium chemical concentration peak in the depth direction.

19. The semiconductor device according to claim 18, wherein
the integrated value of the second helium chemical concentration peak is 1×10¹¹ (/cm²) or more and 1×10¹² (/cm²) or less.

20. The semiconductor device according to claim 18, wherein
the integrated value of the first helium chemical concentration peak is 0.9×10¹¹ (/cm²) or more and 0.9×10¹² (/cm²) or less.

21. The semiconductor device according to claim 1, wherein
the integrated value of the second recombination center density peak in the depth direction is equal to or greater than twice the integrated value of the first recombination center density peak in the depth direction.

22. The semiconductor device according to claim 1, wherein
a peak value of the second recombination center density peak is greater than a peak value of the first recombination center density peak.

23. The semiconductor device according to claim 1, further comprising a base region of a second conductivity type provided between the drift region and the upper surface of the semiconductor substrate, wherein
a depletion layer edge position is located between the first recombination center density peak and the second recombination center density peak, the depletion layer edge position being a position which is closest to the lower surface of the semiconductor substrate reached by a depletion layer expanding from a lower end of the base region toward the lower surface when an avalanche breakdown occurs in the semiconductor device.

24. The semiconductor device according to claim 17, wherein
the integrated value of the recombination center density of the second inter-peak region in the depth direction is equal to or greater than twice the integrated value of the recombination center density of the first inter-peak region in the depth direction.

25. The semiconductor device according to claim 17, wherein
a plurality of recombination center density peaks are provided in any of the inter-peak regions.

26. The semiconductor device according to claim 17, wherein
the plurality of inter-peak regions further include
a third inter-peak region arranged farther away from the lower surface of the semiconductor substrate than the second inter-peak region and provided with one or more third recombination center density peaks.

27. The semiconductor device according to claim 13, wherein
a peak value of the second helium chemical concentration peak is greater than a peak value of the first helium chemical concentration peak.
